(19) United States
(12) Patent Application Publication
(10) Pub. No.: US 2014/0177185 A1
(43) Pub. Date: Jun. 26, 2014

(54) WALL PLATE ASSEMBLY WITH SIGNAL-ADAPTIVE FEATURES

(71) Applicant: Lastar, Inc., Moraine, OH (US)

(72) Inventor: Everett Poffenberger, Dayton, OH (US)

(73) Assignee: Lastar, Inc., Moraine, OH (US)

(21) Appl. No.: 14/083,494

(22) Filed: Nov. 19, 2013

Related U.S. Application Data
(60) Provisional application No. 61/779,807, filed on Mar. 13, 2013.
(60) Provisional application No. 61/745,077, filed on Dec. 21, 2012.

(51) Int. Cl. H05K 7/14; H01R 43/26; H05K 9/00

(52) U.S. Cl. CPC H05K 7/1427; H05K 9/0037; H01R 43/26
USPC 361/752; 29/825

(57) ABSTRACT

A wall plate assembly with a wall plate configured to connect a display signal from a signal source to an HDMI, DVI or VGA-compatible video signal. In one form, the display signal source is a DisplayPort. The wall plate assembly integrates an interchangeable connection into a wall plate assembly to permit HDMI, DVI or VGA interfaces with a DisplayPort signal. The wall plate assembly includes a wall plate defining a face on which one or more signal interfaces extend outward. The wall plate further includes a plurality of bracket tabs integral to the wall plate. A circuit board is coupled to a wall plate. The signal interface is electrically connected to the circuit board. The wall plate assembly includes a housing that is engageable with the wall plate. The housing comprises a plurality of mating tabs integral with the housing, independently compressible with respect to the housing, and alternatively engageable with the plurality of mating tabs. The engageablilty of the housing to the wall plate creates an interchangeable wall plate assembly that performs the functions disclosed herein.

This application claims priority to U.S. Provisional Application 61/745,077, filed Dec. 21, 2012, and to U.S. Provisional Application 61/779,807, filed Mar. 13, 2013.

### BACKGROUND OF THE INVENTION

The present invention relates to termination points for wiring systems and, more particularly to a wall plate assembly that interfaces between video signal sources generated in one format and a wiring system that conveys the signals to one or more receivers configured to accept an HDMI-compatible, DVI-compatible or VGA-compatible video format.

Digital video transmission—which is based on transmission minimized differential signals (TMDS)—has several demonstrated performance advantages over transmission of the same content in the analog domain. One significant advantage is the pixel-for-pixel image mapping and attendant increase in resolution and color accuracy possible when a digital signal remains in the digital domain between a digital source and display.

One popular way to convey uncompressed digital video signals is through a high-definition multimedia interface (HDMI) that is presently available in the high definition consumer electronics market via digital televisions, personal computers (PCs), digital-video-disc (DVD) players, Blu-ray disc players, game consoles and digital-set-top boxes. One beneficial aspect of HDMI is that it is configured as a single cable device, providing efficient, compact structure. Cable connectors employing HDMI protocols have particular size, shape and functional attributes; in fact, there are several HDMI connector types, including Type A, Type B, Type C, Type D and Type E, each with its own size and number of pins. For example, a Type A connector commonly found on high-definition digital televisions has 19 pins and is 13.9 mm wide and 4.45 mm high.

Digital-visual-interface (DVI) is another video signal transmission format present in computer systems, as well as in numerous consumer electronics systems. As with HDMI, DVI employs a particular connector configuration, including number of pins (29 versus HDMI Type A's 19) and signal-carrying capability.

Video-graphics-array (VGA) provides analog signal connectivity, and is especially prevalent in legacy computers (i.e., laptops, PCs) and liquid crystal display (LCD) monitors. In some forms, VGA is compatible with DVI connectors and signals.

The DisplayPort digital signal protocol is based on small packetized digital data transmission using low-voltage differential signaling (LVDS) capable of being conveyed over inexpensive twisted-pair copper cables at varying data throughput levels. In this regard, DisplayPort is similar to HDMI, even though it possesses more than twice the bandwidth of HDMI (i.e., 21.6 Gbit/s as opposed to HDMI's 10.2 Gbit/s). Display Port was created as a standard according to the Video Electronics Standards Association (VESA) in an attempt to alleviate concerns over (among other things) bandwidth and encryption/security associated with DVI and HDMI. Like HDMI, DisplayPort involves the use of a single cable for digital video transmission that can be employed on a suitably-configured television, PC or related electronic device. The DisplayPort standard provides specifications of connectors, cables and data communication protocols used in conveying its signals. As such, its signal is not compatible with (among others) DVI or HDMI, although passive adapter devices may be used in some circumstances (i.e., ports configured to operate in so-called “dual-mode” configurations) to achieve at least some degree of signal converting to permit LVDS to TMDS transformations.

Significantly, each of the transmission protocols discussed above may employ different connectors or related structure such that a consumer may be faced with trying to connect disparate devices through incompatible formats. This problem is compounded by the fact that various legacy products in both the computer and high definition consumer electronics markets employ (in addition to the aforementioned VGA) one or more of the HDMI, DVI or DisplayPort connection features. Any attempt at reconciling the differing ways these signals are generated and coupled to other devices (especially in light of the increasingly evanescent distinctions between computers and high definition consumer electronics) is going to introduce significant increases in overall system layout complexity. For example, it may become necessary to provide separate transmitters configured for each signal format.

### BRIEF SUMMARY OF THE INVENTION

The problems discussed above are overcome by the device of the present invention, which according to a first aspect thereof integrates an interchangeable connection into a wall plate assembly to permit HDMI, DVI or VGA interfaces with a DisplayPort signal. According to a first aspect of the invention, a wall plate assembly includes a wall plate defining a face on which one or more signal interfaces extend outward. The inclusion of a face may be from an integral formation of a surface within the wall plate, or from the attachment of a separate generally planar surface to the wall plate. The wall plate further includes a plurality of bracket tabs integral to the wall plate. A circuit board is coupled to a wall plate and in some embodiments is situated behind the wall plate. The signal interface is electrically connected to the circuit board. In some embodiments, the wall plate assembly includes a cable lead that has a proximal end and a distal end. The wall plate assembly further includes a housing that is engageable with the wall plate. The housing comprises a plurality of mating tabs integral with the housing, independently compressible with respect to the housing, and alternatively engageable with the plurality of mating tabs.

The system of the present invention will provide a simple solution for (among other things) residential and commercial digital video transfer, regardless of the connection configurations of the source and receiver devices. Upon connection of a cable lead to a signal source, the signal carried from the source is conveyed to a receiver (such as a monitor, television, computer screen or the like) through the premise wiring and the wall plate assemblies of the present invention. In the present context, a signal source need not be the location where the signal is generated, but may also include conduit (for example, in the form of electrically conductive wires, cables or the like) that conveys the signal from an originating point to the wall plate assembly. Usage of the term herein will be apparent from the context.

According to another aspect of the invention, a premise wiring system is disclosed that includes one or more of the interchangeable wall plate assemblies as described in the various embodiments of the present invention, and one or more wires electrically connected to these assemblies. The wiring system may include numerous such wall plate assemblies that can be connected to one another through the wires in either a point-to-point configuration or a point-to-multipoint configuration. As mentioned above, the interfaces between the HDMI, DVI or VGA signals and those of a DisplayPort signal include the necessary signal-conversion circuitry. As configured, the wiring system defines a digital video signal conversion and conveying mechanism.

According to another aspect of the invention, a method of connecting premise wiring to a wall plate assembly is disclosed. The method includes arranging at least one wire in a premise wiring system to include a quick-connect coupling at a terminus of the premise wiring system and connecting the quick-connect coupling situated on a wall plate assembly as described in the various embodiments of the present invention. The quick-connect coupling enables fast connection and disconnection with a complementary quick-connect coupling on a signal carrying wire or cable.

### BRIEF DESCRIPTION OF THE SEVERAL VIEWS OF THE DRAWINGS

The following detailed description of specific embodiments of the present invention can be best understood when read in conjunction with the following drawings, where like structure is indicated with like reference numerals and in which:

FIG. 1 illustrates a dongle form factor for connecting an HDMI-compatible signal at one end to a DisplayPort-compatible signal at the other end according to the prior art;

FIG. 2 illustrates an HDMI-compatible Decora-style wall plate according to the prior art;

FIG. 3 illustrates a rear perspective view of an improved wall plate assembly according to an aspect of the present invention;

FIGS. 4A and 4B illustrate respectively a side edge view and a rear perspective view of a mounting bracket and wall plate face according to an aspect of the present invention, highlighting the bendable tabs;

FIG. 5 illustrates a perspective view of a support structure that fits within the housing of the wall plate assembly of the present invention;

FIG. 6 illustrates details associated with a housing that is used to contain the support structure of FIG. 5;

FIGS. 7A through 7C illustrate various views of the wall plate assembly according to an aspect of the present invention that is used to convert a DisplayPort signal into a VGA signal;

FIG. 8 illustrates a view of the wall plate assembly generally similar to that of FIG. 7A, except now to convert a DisplayPort signal into a DVI signal;

FIG. 9 illustrates a view of the wall plate assembly generally similar to that of FIG. 7A, except now to convert a DisplayPort signal into an HDMI signal;

FIG. 10 shows the use of the wall plate assembly of an aspect of the present invention used in conjunction with RapidRun™ cable in an educational or professional environment;

FIG. 11 shows a house using premise wiring and one embodiment of the wall plate assembly of the present invention; and

FIGS. 12A and 12B illustrate various views of the wall plate assembly according to an aspect of the present invention that is used to carry an HDMI signal into and out of the wall plate assembly.

### DETAILED DESCRIPTION OF THE PREFERRED EMBODIMENTS

Referring first to FIG. 1, there are presently numerous adapters on the market configured to convert DisplayPort signals into a form suitable for use with HDMI, VGA or DVI compatibility. As shown, the so-called dongle D form factor includes connectors at opposing ends of a nominal length of cable (for example, 8 inches), and includes electronic circuitry (not presently shown) configured with signal-manipulating features situated within a housing adjacent or contiguous with one of the ends. Lastar Inc. part number 54130, which is manufactured and sold by the Assignee of the present invention, is one such embodiment of this dongle-based form factor. The embodiment shown converts DisplayPort DP to HDMI HD using a male DisplayPort connector (not shown) that mates with a female DisplayPort connector that is resident on the laptop, PC or other computer-related device. The electronics in the dongle housing then converts the DisplayPort-compatible signal to its HDMI-compatible counterpart. From here, a user may then connect the HDMI HD end of the cable via female HDMI connector to a suitably-equipped HDMI signal video monitor or related receiver (not shown). This type of form factor is especially useful for desktop computing applications. Despite the advantages associated with the dongle D form factor, its exposure leaves it susceptible to breakage, misplacement or theft. A different form factor need was identified for professional/commercial use.

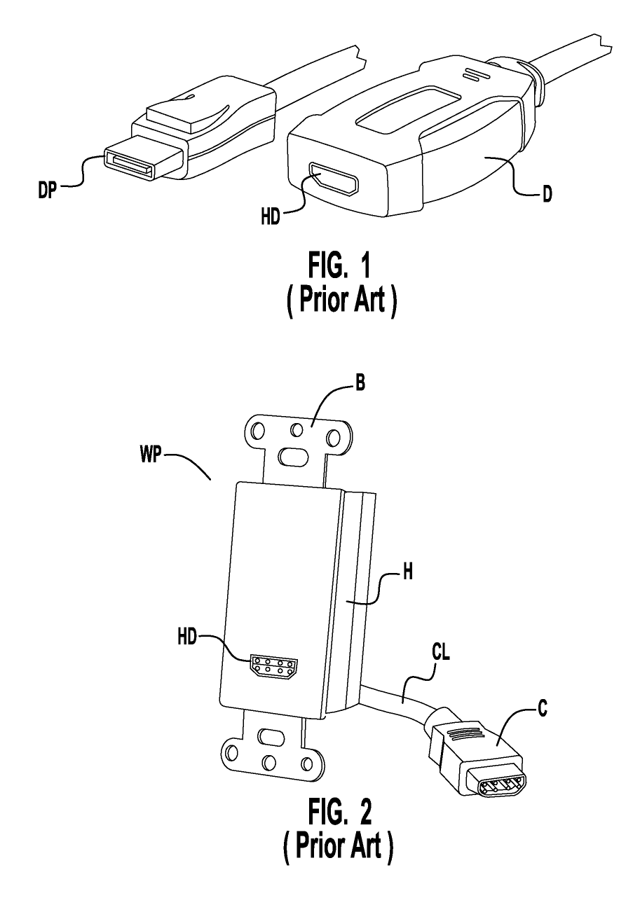

Referring next to FIG. 2, a pass-through Decora-style wall plate WP is shown. Both this version, as well as the interchangeable version discussed below are owned by the Assignee of the present invention. The electronics that convert the DisplayPort signal to HDMI, VGA or DVI are built into the housing H box or related enclosure (also called a case or a back shell) that is attached at the back of the wall plate WP. As shown, a typical wall plate assembly includes—in addition to the wall plate WP, a mounting bracket B, digital signal conversion circuitry (not shown, but for example, in the form of a printed circuit board (PCB) that may include other electronic circuitry) mounted to the mounting bracket B, an interface (also known as a connector, presently shown as HDMI interface HD) and a cable lead (i.e., wire) CL that is terminated with connector C. In a first embodiment of the assembly, the cable lead CL enters through a recessed rectangular cutout formed in the back of housing H to make a connection of the individual wires therein to the appropriate components of the digital circuitry. Securing posts may be tubular such that the rearward-most end may accept threaded screws, rivets or other such fasteners to secure the PCB to the mounting bracket. It will be appreciated by those skilled in the art that other securing means may be used, including glue or related adhesives, welding, soldering or the like. To the extent that the wall plate is removable connection from the housing H or related box, it is still difficult to use because a screwdriver or similar tool must be used to pry the tabs from the housing H. This tends to have an assembly made from such a wall plate WP and housing H combination resemble a permanent use or attachment rather than an interchangeable one.

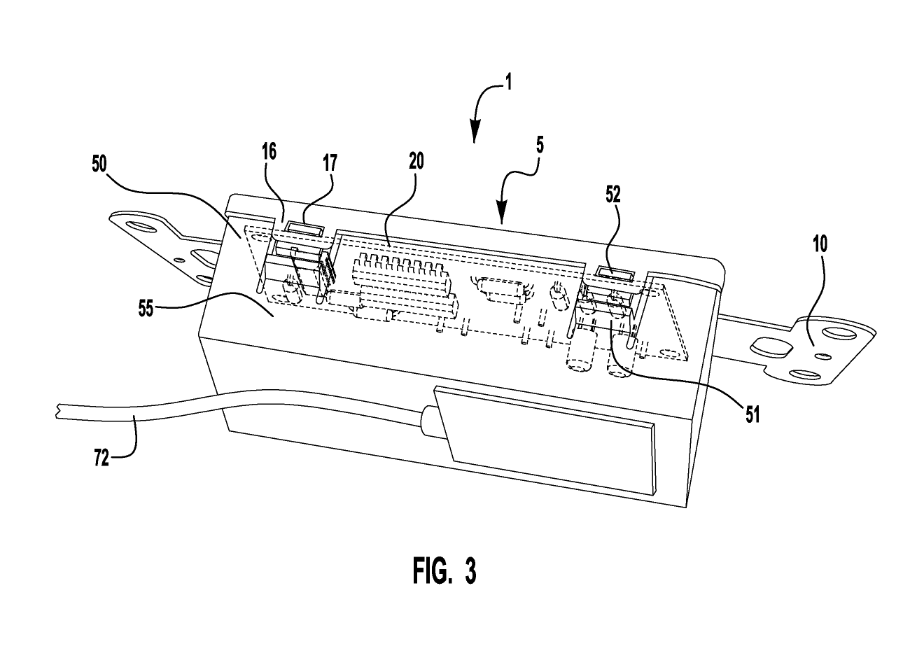

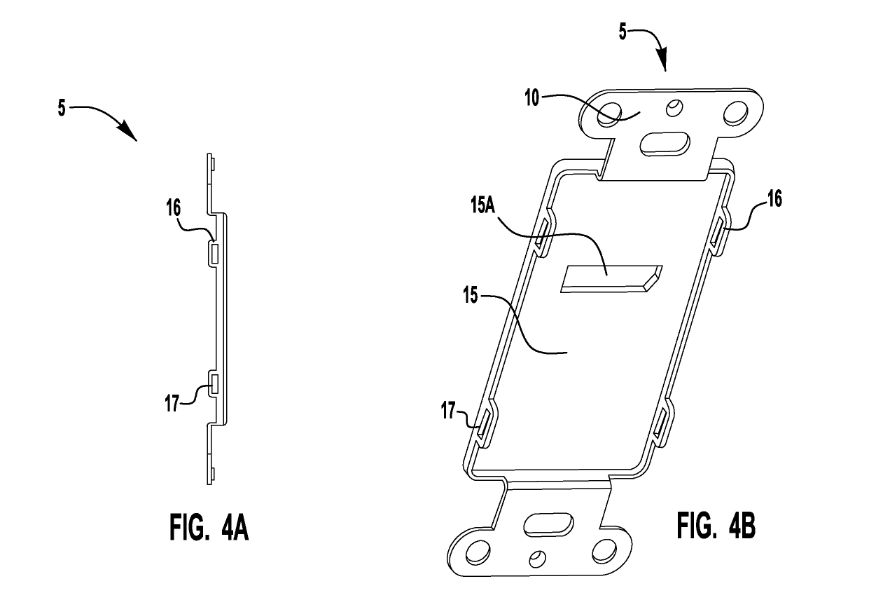

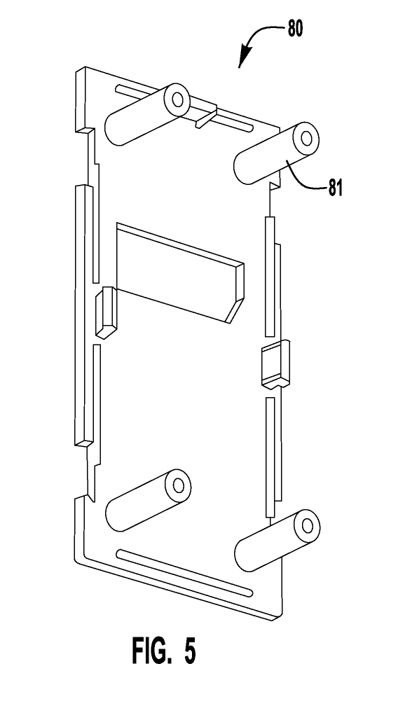

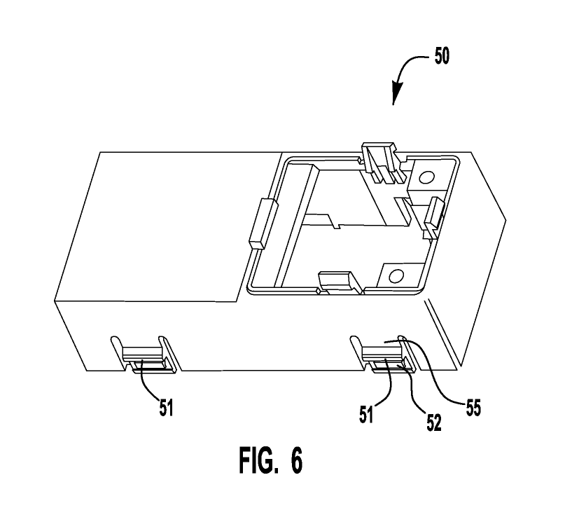

Referring next to FIGS. 3, 4A and 4B, one aspect of a wall plate assembly 1 of the present invention includes an improved Decora-style concept by keeping the same general form factor and dimensions of existing wall plate assemblies while modifying the attachment between the wall plate 5 and the remainder of the assembly 1 to be interchangeable. In situations involving large inventories, this saves inventory resources by having the wall plates 5 be easily changed or attached. In a preferred embodiment, the wall plates 5 employ four common colors on at least a face 15 thereof, including aluminum, white, black and ivory. Face 15 is integrally-formed with a plurality of bracket tabs 16. In some embodiments, a mounting bracket 10 is connected to the wall plate 5; this connection may be an integral connection or a removable connection. In other configurations, the mounting bracket 10 may be formed with or secured to a housing (discussed below).

In one form, the wall plate assembly 1 further comprises a circuit board 20 coupled to the wall plate 5. For example, the circuit board 20 is such that it may generally align with the face 15 of the wall plate 5 and act as an outlet or jack for an electrical signal that may be delivered to the wall plate assembly 1 through a wiring system. The wall plate assembly 1 may also include a box or housing 50 engageable with the wall plate 5 and integral with a plurality of cantilevered mating tabs 51 that are independently compressible with respect to the housing 50. Preferably, the mating tabs 51 are selectively engageable with the bracket tabs 16 through alternating compression and decompression. Significantly, the use of the tabs 16 in bendable form helps facilitate this separation of the wall plate 5 from the housing 50 in a tool-free manner. In particular, mating tabs 51 that are integrally-formed into the housing 50 may be pushed inward on the housing 50. This allows them to pass out of an interference fit with a bracket tab 16 integral to the wall plate 5, thereby allowing easy removal or attachment of the wall plate 5 to the housing 50. Moreover, the snap-fit nature of the mating tabs 51 possess a locking ability to prevent inadvertent disconnection. Significantly, this interchangeability is accomplished without the need for tools. The bracket tabs 16 may also include a cutaway portion 17 while the mating tabs 51 further include a notch portion 52. In one particular form, the bracket tabs 16 are engaged with respective mating tabs 51 when the notch portions 52 of the mating tabs 51 are disposed within the cutaway portions 17 of the bracket tabs 16. Importantly, when an attempt is made to connect the wall plate assembly 1 of the present invention to a device that has a different signal interface (discussed in more detail below) than that of the one that presently extends through the face 15 of wall plate 5, the snap-fit nature of the engagement between tabs 16 and 17 permits rapid replacement of the wall plate 5 to ensure the proper signal interface is securely put in place within the housing 50 of assembly 1 without recourse to screwdrivers or other tools.

Wall plate assembly 1 may further include one signal interfaces (shown later) extending outward through an aperture 15A formed in the face 15 of the wall plate 5; such a signal interface is electrically connected to the circuit board 20. The signal interface is configured such that upon connection of the wall plate assembly 1 to a signal source (such as a computer (not shown)) as well as a sink device, projector or display 60, the signal interface can carry an electronic signal. In some embodiments, the signal interface is selected from a group consisting of DisplayPort, HDMI, DVI or VGA, and combinations thereof. In some embodiments, the wall plate assembly 1 inputs a DisplayPort source signal, which passes through the digital signal conversion circuitry of the circuit board 20, and outputs a signal through the signal interface from the group consisting of HDMI, DVI or VGA, and combinations thereof.

Furthermore, the mix-and-match approach (by one or more of color or termination point (also called signal interface, discussed in more detail below)) allows the use of multiple different adapter type housings 50 and related assemblies 1 that could be used as part of the present invention. For example, a DisplayPort-to-HDMI, DisplayPort-to-VGA and DisplayPort-to-DVI configuration may readily be formed and interchanged. Housing 50 may include an electromagnetic shield (not shown) to substantially enclose the circuit board 20. The present invention is configured such that when the housing 50 detaches from the wall plate 5, the internal components of assembly 1 typically stay with the wall plate 5. In any event, the housing 50 that contains the electronics—when coupled to the wall plate 5—is referred to as part of the wall plate assembly 1. In some instances (not shown), the electronics could be situated elsewhere such that they would not be mounted to any part of the wall plate assembly 1.

Referring next to FIG. 5 in conjunction with FIG. 3, in a particular form, the circuit board 20 is a PCB and comprises digital signal conversion circuitry configured to adapt a DisplayPort signal to at least one of HDMI, DVI and VGA. Such a circuit board 20 may be engaged with the wall plate 5 through posts 81 that form a unitary structure or support structure 80 with and extend rearwardly from the wall plate 5. In some embodiments, the posts 81 are tubular such that a rearward end of the posts 81 are configured to accept screws or related fasteners to secure the circuit board 20 to the wall plate 5.

The wall plate assembly 1 may additionally include a cable lead 72 that is in electrical communication with the at least one signal interface through the circuit board 20; in a preferred form, a distal end of the cable lead 72 may include a quick-connect coupling to electrically connect the signal source to the wall plate assembly 1. In the present context, the term “cable lead” defines a cable, wire, or related electrical signal-carrying member that represents either the wall plate termination to the runner cable or the flying lead termination to a runner cable. The quick-connect nature of the distal end of the cable lead 72 provides a secure and fast coupling with a mating quick-connect electrical connector of a runner cable completing a number of different functioning electrical signals, for example DisplayPort. In this manner, wall plate assembly 1 according to the present invention can be connected via runner cable to a second wall plate or a flying lead to enable relatively rapid and simple installation of a premise wiring system. In some embodiments the runner cable is a wire (as will be discussed and shown in more detail below).

In some embodiments, the length of the cable lead 72 is such that the quick-connect coupling is adjacent to the wall plate 5. In the present context, to be included within the meaning of the term “adjacent”, precise side-by-side spacing between the components is not necessary. More particularly, the term is utilized herein to distinguish the quick-connect assembly of the cable lead of the present invention from contemplated wiring systems where a length of cable coupled to a wall plate runs from the wall plate to a connector in a location displaced far enough from the wall plate to make it inaccessible to the installer, absent relocation of the installers base of operation to another room within the structure or another part of a room within the structure. In some embodiments, the wall plate assembly 1 further comprises a permanent connection between the cable lead 72 and the circuit board 20. In this embodiment, when the housing 50 is removed from the wall plate 5, the cable lead 72 stays with the wall plate 5. In some embodiments, the cable lead 72 is removably engageable with the circuit board 20 and the wall plate 5. In this embodiment, when the housing 50 is removed from the wall plate 5, the cable lead 72 stays with the housing 50. In other more particular forms, the cable lead 72 comprises a male distal end and a female proximal end, while in others, it may be just the opposite.

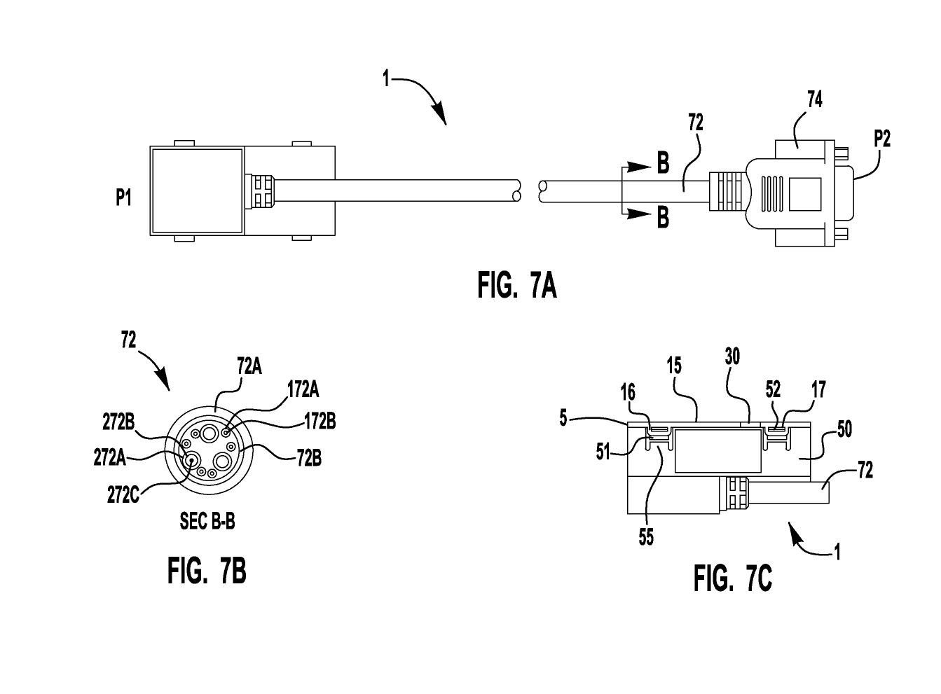

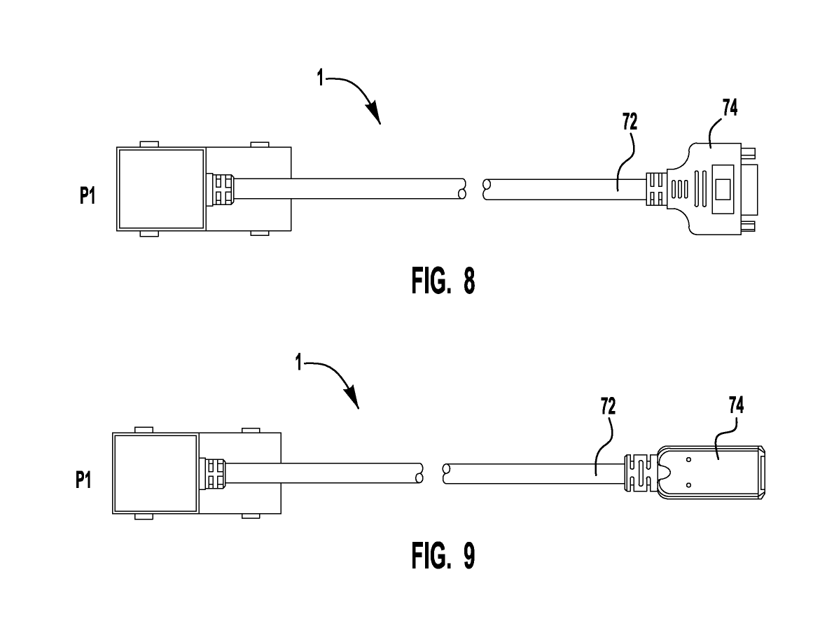

Referring next to FIGS. 7A through 7C, 8 and 9, various versions of the DisplayPort interfaces for VGA (FIGS. 7A through 7C) DVI (FIG. 8) and HDMI (FIG. 9) are shown. Regardless of the termination at the end of cable lead or wire 72, it is preferable to have quick-connect couplings 74 to facilitate tool-free connection and disconnection. While the present figures do not specify the nature of the signal-converting electronics, they do show basic cable connections, as well as connections via the cable output through the quick-connect couplings 74. Furthermore, it will be appreciated by those skilled in the art that a PCB or related circuit board 20 (such as that shown in FIG. 3) that contains such signal-converting electronics may be mounted within the housing 50 of assembly 1. Significantly, all of the assemblies 1 of the present invention employ a convenient form factor that mimics the connectivity of an existing dongle form factor into an interchangeable wall plate 5 form factor. As such, the installation relative to a dongle form factor is improved, as it uses fewer connections. Moreover, it is better aesthetically in that it reduces the clutter associated with excess wiring, while the interchangeable wall plate can match the most common wall plate colors (such as those mentioned above). Furthermore, the present approach is less-susceptible to being stolen or lost.

As such, the present invention may be configured in a variety of ways. In one form, it may include adapters to permit a DisplayPort-originated signal to be passed through an appropriately-configured wall plate 5 on its way to an HDMI, DVI or VGA-compatible receiver. As mentioned above, in a particular form, the wall plates 5 may be of the Decora-style variety.

In yet another form, the wall plates 5 can be made to be easily (i.e., free of tools) interchangeable through the complementary tabs 16 and 51 such that the connector formed in the wall plates 5 may be swapped in and out without having to replace greater amounts of premise wiring infrastructure. Moreover, additional wall plate 5 form factors may also be used in conjunction with the present invention, including full-size wall plates, plates, double-gang wall plates and combination wall plates that could include adding VGA or other suitable connections.

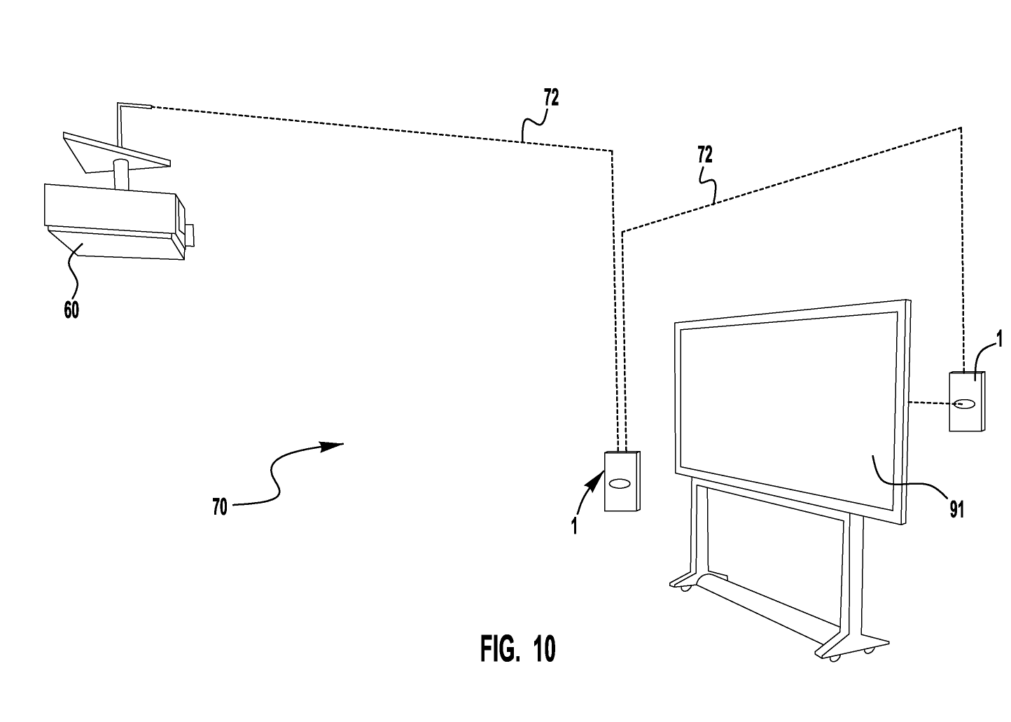

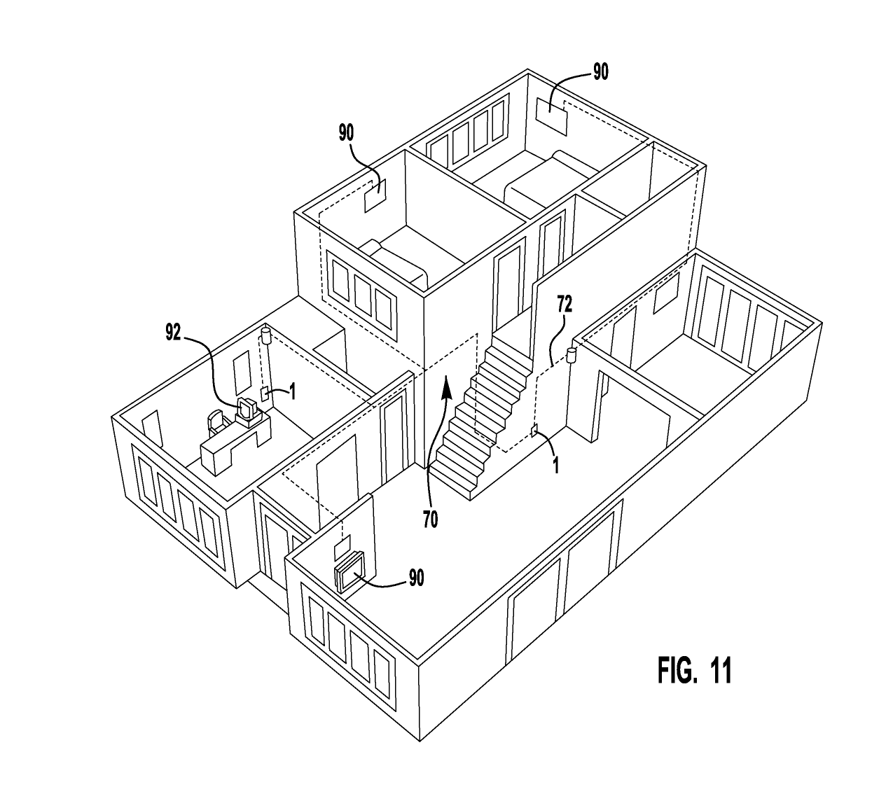

Referring next to FIGS. 10 and 11, the placement of the interchangeable wall plate assemblies of the present invention within a typical setting (FIG. 10)—where the sink or display 60 may be in the same room as the source (not shown)—and as part of a wiring system where the sink or display 60 may not be in the same room. In either configuration, a premise wiring system 70 may include one of the various embodiments of a wall plate assembly 1 of the present disclosure. For example, the premise wiring system 70 may include one or more wires 72 comprising a quick-connect coupling 74 (as discussed above in conjunction with FIGS. 7A through 9) on at least one end such that upon engagement of the quick-connect coupling 74 to a compatible quick-connect coupling of another cable (for example, one generally similar to that of wire 72), a signal is transmitted through the wire 72 and is conveyed to the signal interface 30 that may be selected from a group consisting of DisplayPort, HDMI, DVI or VGA, and combinations thereof. In some embodiments, the premise wiring system 70 inputs a DisplayPort source signal, which passes through the digital signal conversion circuitry of the circuit board 20, and outputs a signal through such signal interfaces 30.

It will be appreciated that various forms of cable lead or wire 72 may be used. In one exemplary form (shown in cross-sectional view in FIG. 7B), wire 72 is made up of a polyvinylchloride (PVC) jacket 72A, one or more shields (for example, braided shield) 72B, and various signal-carrying conductive members 172 and 272. Smaller conductive members 172 (which include colored PVC insulation 172A around a metallic core 172B) may be used to carry horizontal and vertical synchronizing signals. Other signal-carrying interface configurations (such as one between HDMI and DVI) will—although of a different construction—be similarly configured mutatis mutandis with comparable smaller signal-carrying conductive members, while the larger conductive members 272 (which include colored PVC insulation 272A around a metallic core 272B) may be used for mini coax applications, where the well-known red, green and blue signaling cables are employed.

Premise wiring system 70 may be made up of numerous wall plate assemblies 1 that may be connected to one another through one or more of the aforementioned wires 72 in a point-to-point configuration. In other embodiments, this connection is a point-to-multipoint configuration. The wiring system 70 can be responsive to input from a digital signal source, such as a television 90, central control panel (which may be connected to a multimedia system or the like), display monitor 91 or computer 92. As shown with particularity in FIG. 11, wall plate assemblies 1 can form either a terminus point or an intermediary point within wiring system 70. Premise wiring may be legacy (for example, the popular RapidRun™ cable shown in FIG. 11 that is manufactured and sold by the Assignee of the present invention) or newly-installed to take particular advantage of the high digital signal bandwidth. Another wiring system may be based on the protocol shown with particularity in FIG. 10.

A method of connecting premise wiring to a wall plate assembly 1 includes arranging at least one wire 72 in a premise wiring system 70 to include a quick-connect coupling at a terminus of the premise wiring system 70 and connecting the quick-connect coupling to a complementary quick-connect coupling quick-connect couplings 74 situated on a wall plate assembly 1. In some embodiments, the complementary quick-connect coupling 74 is connected to a cable (such as wire 72) of the wall plate assembly 1. It is contemplated that the wall plate assembly 1 of the method may comprise any of the various embodiments of the wall plate assembly 1 discussed in the present disclosure. The method may further include permanently connecting the complementary quick-connect coupling to the circuit board 20 and/or the wall plate 5. In some embodiments, the method further comprises reducing tension on the wall plate assembly 1 and the at least one wire 72 in the premise wiring system 70 by placing a strain relief device 73 between the at least one wire 72 in the premise wiring system 70 and the circuit board 20. Preferably, the method further comprises providing a housing 50 of the wall plate assembly 1 that is engageable with the wall plate 5 without the use of tools to permit rapid changing of the wall plates 5 and their signal interface-specific termination configuration that is formed in the face 15.

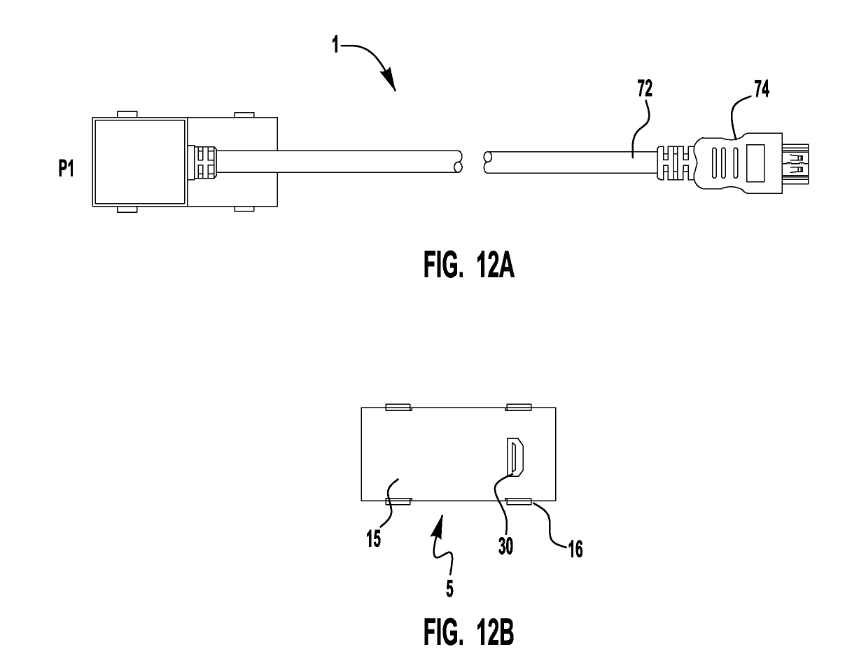

Referring next to FIGS. 12A and 12B, another embodiment of an interface and a wiring system is shown. In this embodiment, the interchangeable wall plate assembly 1 is contemplated with an input signal comprising HDMI signal interface 30 (shown on the wall plate face 15 in FIG. 12B) and an output signal comprising HDMI at the right end of wire 72 in FIG. 12A. In some embodiments, an HDMI signal is carried into the quick-connect coupling system and is transferred through wall plate assembly 1 with the interchangeability of the wall plate 5 of the various embodiments described in this disclosure. Significantly, all of the adapters of the embodiment employ a convenient form factor that mimics the connectivity of the existing dongle form factor into an interchangeable wall plate form factor to improve installation relative to the aforementioned dongle form factor.

Having described the invention in detail and by reference to specific embodiments thereof, it will be apparent that modifications and variations are possible without departing from the scope of the invention defined in the appended claims. More specifically, although some aspects of the present invention are identified herein as preferred or particularly advantageous, it is contemplated that the present invention is not necessarily limited to these preferred aspects of the invention. For example, it is noted that the electrical connectors, the electrical wiring, and the male and female quick-connect couplings illustrated in the figures can be presented in a variety of configurations without departing from the scope of the present invention.

What is claimed is:

1. A wall plate assembly comprising:
a wall plate defining a face with a plurality of bracket tabs integrally formed thereon;
a circuit board;
a housing engageable with said wall plate;
a mounting bracket connected to at least one of said wall plate and said housing;
a plurality of mating tabs integral with said housing and selectively engageable with said plurality of bracket tabs, wherein at least one said plurality of mating tabs or at least one of said plurality of bracket tabs are independently compressible to permit said selective engagement therebetween;
at least one signal interface extending outward from said face and electrically connected to said circuit board, said at least one signal interface configured such that upon connection of said wall plate assembly to a signal source, said at least one signal interface can carry an electronic signal; and
a cable lead comprising a proximal end that is in electrical communication with said at least one signal interface through said circuit board, and a distal end comprising a quick-connect coupling to electrically connect to said signal source.

2. The wall plate assembly of claim 1, wherein said housing comprises an electromagnetic shield configured to substantially enclose said circuit board.

3. The wall plate assembly of claim 1, wherein said at least one signal interface comprises a plurality of signal interfaces selected from the group consisting of DisplayPort, HDMI, DVI, VGA and combinations thereof.

4. The wall plate assembly of claim 1 wherein said plurality of bracket tabs further comprise a cutaway portion and said plurality of mating tabs further comprise a notch portion such that said selectively engageable connection defines an interference fit.

5. The wall plate assembly of claim 1, wherein at least one of said plurality of mating tabs and said plurality of mating tabs define a cantilevered construction.

6. The wall plate assembly of claim 1, wherein said circuit board comprises digital signal conversion circuitry configured to adapt a DisplayPort signal to at least one of HDMI, DVI and VGA signals.

7. The wall plate assembly of claim 1, wherein said circuit board is engaged with said wall plate through posts that form a unitary structure therebetween.

8. The wall plate assembly of claim 1, wherein said wall plate comprises a colored surface configured to match a color scheme of a wall on which said wall plate assembly is formed.

9. A premise wiring system comprising:
a wall plate assembly comprising:
a wall plate defining a face with a plurality of bracket tabs integrally formed thereon;
a circuit board;
a housing engageable with said wall plate;
a mounting bracket connected to at least one of said wall plate and said housing;
a plurality of mating tabs integral with said housing and selectively engageable with said plurality of bracket tabs, wherein at least one said plurality of mating tabs or at least one of said plurality of bracket tabs are independently compressible to permit said selective engagement therebetween;
at least one signal interface extending outward from said face and electrically connected to said circuit board, said at least one signal interface configured such that upon connection of said wall plate assembly to a signal source, said at least one signal interface can carry an electronic signal; and
a cable lead comprising a proximal end that is in electrical communication with said at least one signal interface through said circuit board, and a distal end comprising a quick-connect coupling to electrically connect to said signal source; and
at least one wire coupled to said wall plate assembly to define a signal path between said at least one wire and said at least one signal interface.

10. The premise wiring system of claim 9, wherein said at least one signal interface comprises a plurality of signal interfaces selected from the group consisting of DisplayPort, HDMI, DVI, VGA and combinations thereof.

11. The premise wiring system of claim 9, wherein said wall plate assembly inputs a DisplayPort source signal and said wall plate assembly outputs a signal from the group consisting of HDMI, DVI, VGA and combinations thereof.

12. The premise wiring system of claim 9, wherein said circuit board comprises digital signal conversion circuitry configured to adapt a DisplayPort signal to at least one of HDMI, DVI and VGA signals.

13. The premise wiring system of claim 9, wherein said wherein said plurality of bracket tabs further comprise a cutaway portion and said plurality of mating tabs further comprise a notch portion such that said selectively engageable connection defines an interference fit.

14. The premise wiring system of claim 9, further comprising a plurality of said wall plate assemblies connected to one another through said at least one wire in a point-to-point configuration.

15. The premise wiring system of claim 9, further comprising a plurality of said wall plate assemblies connected to one another through said at least one wire in a point-to-multipoint configuration.

16. The premise wiring system of claim 9, wherein said at least one wire comprises a quick-connect coupling on at least one end thereof that is cooperatively engageable with said quick-connect coupling of said cable lead to form said signal path.

17. A method of connecting premise wiring to a wall plate assembly, the method comprising:
arranging at least one wire in a premise wiring system to include a quick-connect coupling at a terminus thereof; and
connecting the quick-connect coupling to a complementary quick-connect coupling situated on a wall plate assembly, said wall plate assembly comprising:
a wall plate defining a face with a plurality of bracket tabs integrally formed thereon;
a circuit board;
a housing engageable with said wall plate;
a mounting bracket connected to at least one of said wall plate and said housing;
a plurality of mating tabs integral with said housing and selectively engageable with said plurality of bracket tabs, wherein at least one said plurality of mating tabs or at least one of said plurality of bracket tabs are independently compressible to permit said selective engagement therebetween;
at least one signal interface extending outward from said face and electrically connected to said circuit board, said at least one signal interface configured such that upon connection of said wall plate assembly to a signal source, said at least one signal interface can carry an electronic signal; and
a cable lead comprising a proximal end that is in electrical communication with said at least one signal interface through said circuit board, and a distal end comprising a quick-connect coupling to electrically connect to said signal source.

18. The method of claim 17, further comprising permanently connecting said complementary quick-connect coupling to said circuit board and said wall plate.

19. The method of claim 17, further comprising reducing tension on said wall plate assembly and said at least one wire in said premise wiring system by placing a strain relief device between said at least one wire in said premise wiring system and said circuit board.

20. The method of claim 17, further comprising configuring said at least one signal interface to be compatible with a device connected thereto by securely engaging said wall plate to said housing without the use of tools.

21. The method of claim 20, wherein said at least one signal interface is selected from the group consisting of HDMI, DVI, VGA and combinations thereof.

22. The method of claim 21, wherein said signal source comprises a digital signal protocol that is based on small packetized digital data transmission using a low-voltage differential signaling digital signal.
